(19) United States
(12) Patent Application Publication
(10) Pub. No.: US 2007/0139150 A1
(43) Pub. Date: Jun. 21, 2007

(54) Vapor induced self-assembly and electrode sealing

(75) Inventors: Eugene M. Chow, Fremont, CA (US); Christopher L. Chua, San Jose, CA (US); Koenraad F. Van Schuylenbergh, Sunnyvale, CA (US)

Correspondence Address: PATENT DOCUMENTATION CENTER, XEROX CORPORATION, 100 CLINTON AVENUE SOUTH, XEROX SQ. 20 TH FLOOR, ROCHESTER, NY, 14644, US

(73) Assignee: Palo Alto Research Center Incorporated

(21) Appl. No.: 11/300,860

(22) Filed: Dec. 15, 2005

(51) Int. Cl. H01F 5/00

(52) U.S. Cl. 336/200

(57) ABSTRACT

A method of reflowing a polymer to form a spring or coil structure is described. A polymer is deposited over stress engineered thin film with an internal stress gradient. The polymer serves as a loading prevent release of the internal stress until a solvent vapor softens and reflows the polymer. As the polymer softens, the internal stress within the thin film is gradually released allowing controlled curling of the thin film out of a substrate plane. In one embodiment, the thin film forms the windings of a coil structure.

### BACKGROUND

Inductors have been among the most difficult circuit elements to form on an integrated circuit. Principle challenges include finding ways to form coil structure that are easy to replicate in a mass produced semiconductor processing environment.

One method of fabricating coils has been to use self assembled stress engineered thin films to form a coil structure. In the stress-engineered thin film process, a first portion of a metal strip is deposited over a substrate and a second portion of the metal strip is deposited over a release layer. The metal is deposited such that an internal stress exists in the metal. After the release layer is removed, usually via etching, the second portion of the metal strip curls to form a winding of the coil. A load layer deposited over the second portion of the metal strip controls the amount of curling.

Many different materials may be used as the load layer. In one implementation, a polymer acts as a load layer that controls the curling of the metal. When a polymer is used for loading, the polymer is heated to temperatures of around 180 to 290° C. The amount of heating controls the reflow rate of the polymer. The reflow rate of the polymer controls the amount of curling. Thus higher temperatures cause more polymer softening and allows the stress-engineered thin film to further curl out of the plane of the substrate.

Several problems arise from the above described technique. A first problem is that heating the polymer to such temperatures can cause the polymer to burn. Burned polymer can be hard to remove in subsequent processing steps.

A second problem with this coil fabrication technique is the close proximity of coil windings. Stress-engineered thin films are often formed from metals that are alloys and may not have the highest conductivity. In order to enhance coil conductivity, the coil may be plated with a higher conductivity metal. However, the close proximity and the unusual fields that exist around the coil base (the first portion of the metal) can cause the plating material to short adjacent windings.

Thus an improved method of loading the stress-engineered thin film springs and also of sealing the electrodes is needed.

### SUMMARY

An improved method for reflowing a polymer layer is described. The method involves placing the polymer laser in an enclosed environment and exposing the polymer to a solvent vapor such as an acetone vapor. The solvent vapor softens the polymer. The described method is particularly suitable for reflowing polymer used to load release portions of coil structures and to seal the metal edges prior to plating the coil structures.

### BRIEF DESCRIPTION OF THE DRAWINGS

FIG. 1 shows a side cross sectional view of a deposited stress-engineered thin film spring.

FIG. 2 shows a top view of an array of stress-engineered thin film spring used to form a coil before metal uplift including the regions where polymer is deposited.

FIG. 3 shows a simple chamber for vapor-induced polymer reflow.

FIG. 4 is a flowchart that shows the operations involved in coil formation.

FIG. 5 shows a side view of an example sample of stress-engineered thin film loaded with polymer for use in fabricating a coil structure.

FIG. 6 shows a side view of a coil formed from the sample structure of FIG. 5.

FIG. 7 shows a perspective view of the coil structure formed from the structures of FIG. 5 and FIG. 6.

FIG. 8 shows an example of the coil assembly formed from the mask of FIG. 2.

FIG. 9 shows a cross sectional view of a polymer deposited over a stress engineered thin film prior to polymer reflow.

FIG. 10 shows a cross sectional view of the structure of FIG. 9 after polymer reflow.

### DETAILED DESCRIPTION

An improved method of forming microcoil structures is described. The microcoil structures are particularly useful in forming integrated circuit (IC) solenoid type devices and/or inductors. The improved method uses a solvent vapor to soften and/or reflow a polymer avoiding many of the problems associated with using heat or liquid acetone for polymer reflow.

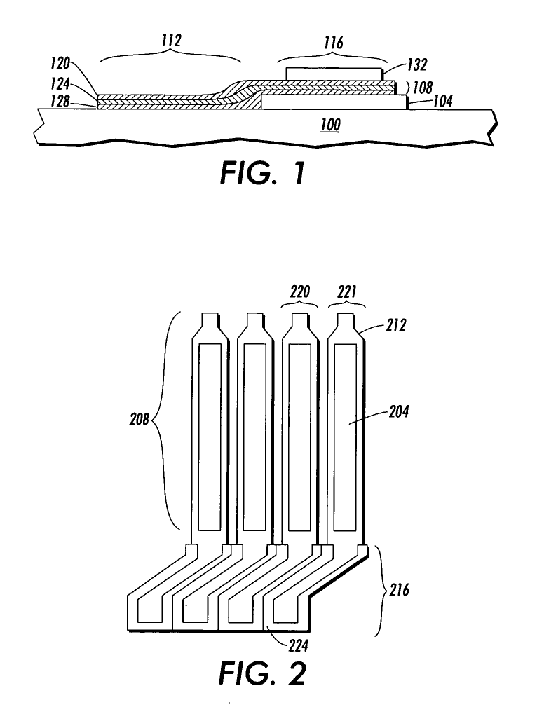

FIG. 1 shows a side cross sectional view of a stress-engineered thin film configured for coil fabrication. In FIG. 1, a release material 104 is deposited over a portion of a substrate 100. A coil material such as “stressed” metal 108 is deposited over release material 104 and substrate 100. Release material 104 is an etchable material such as titanium, silicon nitride, or silicon. Substrate 100 is typically a suitable dielectric layer such as Benzocyclobutene on Silicon, glass, quartz, flex, plastic, FR4 printed circuit board, or Gallium Arsenide. Stress-engineered thin film 108 includes a fixed portion 112 that is deposited directly over, and bonds to substrate 100. Stress-engineered thin film 108 also includes a release portion 116 deposited over release material 104. A polymer layer 132 is deposited over at least the release portion 116 of stress-engineered thin film 108.

As used herein, a stress-engineered thin film is defined as a material that includes a built in stress differential. The stress differential is produced in the spring material by one of several techniques. According to one technique, different materials are deposited in layers, each having a desired stress characteristic, for example a tensile layer formed over a compressive layer. According to another technique a single layer is provide with an intrinsic stress differential by altering the fabrication parameters as the layer is deposited. The spring material is typically a metal or metal alloy (e.g., Mo, MoCr, W, Ni, NiZr, Cu), and is typically chosen for its ability to retain large amounts of internal stress. Microsprings are typically produced using known photolithography techniques to permit integration of the microsprings with other devices and interconnections formed on a common substrate. Indeed, such devices may be constructed on a substrate upon which electronic circuitry and/or elements have previously been formed.

In one example of fabricating a stress-engineered thin film, a metal or metal alloy is deposited in such a way that an internal stress gradient is built into the metal. In one example, stress-engineered thin film 108 is a nickel-zirconium alloy although many other materials may also be used. Typically, stress-engineered thin film 108 is deposited in a series of sublayers, 120, 124, 128 to create the internal stress gradient. Electroless or electroplating techniques may be used to deposit the stressed metal. For example, the built in stress gradient may be obtained by plating from two baths with different concentrations or by varying the current density during plating.

In another example technique, the sublayers are sputtered such that the atomic spacing is larger in the upper sublayers of the spring material resulting in a stress gradient. Different stress levels can be introduced into each sublayer of the deposited stress metal during sputter deposition in a variety of ways including adding a reactive gas to the plasma, varying the deposition angle or changing the pressure of the plasma gas. Varying the pressure of the plasma gas (typically argon) during deposition provides the simplest method of varying stress in deposited sublayers. As the pressure of the plasma gas increases, the film stress in the deposited layers becomes more tensile. Thus, by increasing pressure, a stress which is more compressive in the lower sublayers of the metal layer and that becomes increasingly tensile towards the upper sublayers of the metal layer is formed. A more detailed description of forming such stress gradients is provided in U.S. Pat. No. 5,613,861 entitled “Photolithographically Patterned Spring Contact” by Donald Smith et al. and hereby incorporated by reference in its entirety.

When the spring is ready to be released and to form a coil structure, release material 104 is etched away using an etchant. Etching the release material separates the release portion 116 of the stress-engineered thin film 108 from substrate 100. After release layer removal, only the loading provided by polymer layer 132 such as a photo-resist prevents release portion 116 from curling out of a plane parallel to a surface of substrate 100.

The rate and amount of polymer softening and reflow controls coil formation. In particular, after release layer removal, the reflow and softening of the loading polymer controls the release of the stress in stress-engineered thin film 108. Typically, a coil with 450 and 600 um diameter windings are particularly suitable for IC inductor formation.

FIG. 2 shows a top view of an example mask used to create an array of stress metal release portions for fabricating a coil structure. FIG. 2 shows polymer load 204 on top of a release portion 208 of stress metal 212. A fixed portion 216 of stress-engineered thin film 212 couples to a substrate and is in a ground plane (not shown). Fixed portion 216 forms a base of the coil. In the example shown, each “mask winding”, such as mask winding 221 is electrically isolated from adjacent mask winding 220 such that prior to release, each mask winding is electrically isolated. To preserve the electrical isolation and prevent electrical shorts from forming during plating, polymer 224 is deposited in close proximity to the edge of each stress-engineered thin film fixed portions 216.

FIG. 2 shows one mask pattern; however, other mask patterns are also possible. Example alternative mask structures are shown in U.S. Pat. No. 6,621,141 entitled “Out-Of-Plane Microcoil with Ground-Plane Structure” by Van Schuylenbergh et al filed Sep. 16, 2003 and hereby incorporated by reference. In each mask, a polymer may be deposited in at least two regions of the stressed metal, a first portion of the polymer used on the release portion of the stress metal winding acts as a load layer. When acting as a load layer, the polymer is typically deposited in the release portion center away from the edges of the stress-engineered thin film. A second portion of the polymer seals the metal edges on the fixed portion of the stress-engineered thin film. In the fixed portion, the polymer is deposited near the stress-engineered thin film edges. During reflow, the polymer seals these edges to prevent plating near these edges.

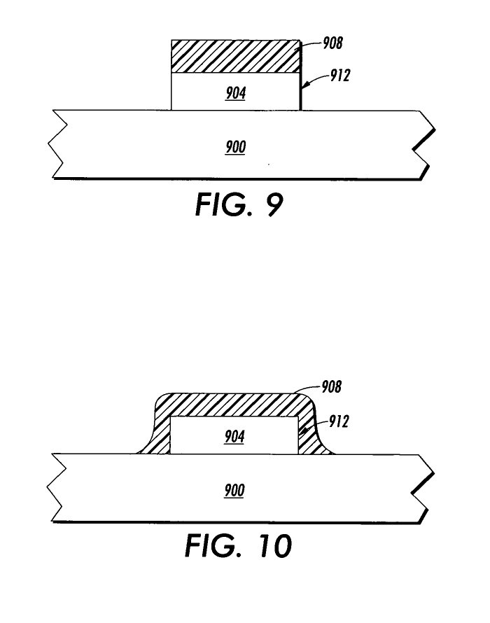

An example of edge sealing is shown in FIG. 9 and FIG. 10. FIG. 9 shows a cross sectional view of the fixed portion of a stress engineered thin film. In FIG. 9 a stress engineered thin film 904 is deposited over a substrate 900. Polymer 908, typically the same polymer that serves as a load layer in the portion of the stress engineered film to be released, is deposited over the thin film 904. Note that the polymer 908 is deposited very close to an edge of 912 of the thin film 904.

In order to reflow the polymer, the polymer is exposed to a solvent vapor. The solvent vapor initially softens the polymer. After extreme softening, the polymer reflows. The reflow causes polymer 908 to flow over the edge 912 of the thin film. Typically the polymer is formed within 5 micrometers of the thin film edge to facilitate reflow sealing. After reflow, the polymer contacts the substrate 900 and seals thin film edge 912 as shown in FIG. 10. When the thin film is carrying a current, a sealed thin film edge helps prevent leakage current.

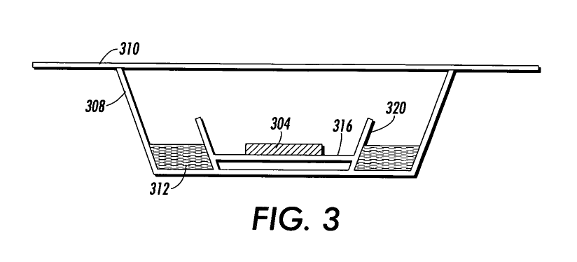

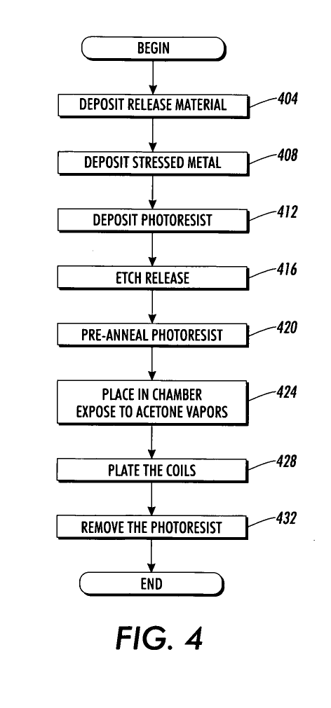

After etching away the release layer, the polymer is softened and/or reflowed. Traditional polymer reflow uses heat or a liquid chemical applied directly to the polymer. However, it has been found that using a vapor induced reflow improves the removability of the polymer in later processing steps. FIG. 3 shows a simple set up for a vapor induced coil assembly reflow. FIG. 4 is a flow diagram showing the various operations used to fabricate the coil.

In FIG. 3, a sample 304 including the released stress metal and the loading polymer is deposited within an outer container 308. Typically outer container 308 is sealed, such as with a cover 310. In one embodiment, a solvent such as acetone 312 forms a vapor that softens polymer deposited within outer container 308. Other example solvent vapors capable of softening a polymer include but are not limited to Futurex by Futurex Co., isopropyl alcohol, methanol and SVC 150. Example polymers include but are not limited to photoresist, electron beam resist and polyimide. In one implementation, a platform 316 keeps the sample elevated within outer container 308 to prevent contact with any liquids such as liquid acetone 312. In an alternate embodiment, the sample may be kept in a smaller container 320 to prevent contact with liquid acetone. In still another technique, there is no liquid acetone within outer container 308 which serves as a sealed reflow chamber, instead, acetone vapor is pumped with a regulated flow of air into the sealed container that contains sample 304. In all the various embodiments, direct contact with a liquid is avoided.

Increased acetone vapor concentration may be created by boiling the acetone. Acetone boils around 57 degrees centigrade. Other solvents may boil at higher temperatures, for example SVC 150 boils around 80 degrees centigrade and Futurex boils at around 110 degrees centigrade. Lowering the surrounding pressure allows the solvents to boil at lower temperatures. The acetone vapor partially dissolves and softens the polymer load on the sample allowing internal stresses in the stress-engineered thin film to release. When sealing is desired, significant softening may result in polymer reflow. The amount of acetone in the ambient controls how quickly the photoresist softens. The higher the acetone partial pressure, the faster the photoresist softens. A desired partial pressure can be established by using standard mass flow controllers to meter a controlled flow of carrier gas such as nitrogen through an acetone bubbler into the reflow chamber. In practice, we found that simply placing a 25 ml beaker of acetone in a sealed 0.25 ft³ reflow chamber creates an environment that is adequate for achieving controllable reflow. The beaker of acetone establishes a natural equilibrium partial pressure with the volume of air in the chamber. The volume of acetone needed can be easily scaled with other chamber sizes to achieve a desired partial pressure of solvent. When the amount of solvent is sufficient such that some liquid solvent remains in the chamber, the atmosphere in the reflow chamber is considered “saturated”.

To control the process of softening and/or reflow, the solvent vapor is regulated. As used herein regulated means controlled. Various methods of regulating the solvent vapor exist. In a first method, a determined quantity of liquid solvent is placed with a fixed volume of air in a sealed container as shown in FIG. 3. The partial pressure is known because the amount of solvent that evaporates is known. In a second method, mass flow controllers meter the flow of carrier gas and the quantity of solvent vapor into a reflow chamber. In all cases, the sample is in an enclosed environment. As used herein, an “enclosed environment” merely means that the sample is in an environment where a concentration of solvent vapor around the sample can be maintained for a desired duration.

As used herein, polymer reflow is defined as a decrease in the polymer Young's modulus; i.e., becoming softer than its room temperature stiffness. When used as a load layer, an important property of the polymer (resist) is the dramatic lowering of polymer stiffness when heated. Sufficient softening to allow flow off of an edge is important only for sealing edges for plating. For loading control purposes, such a significant softening is not necessary. Gradual stiffness reductions result in higher yields compared to systems that quickly reduce the stiffness.

In the current example, in the release portion of the stress-engineered thin film, the polymer flow weakens the rigidity of the polymer allowing gradual release of the internal stress in the stress-engineered thin film and curling of the stress-engineered thin film out of the plane of the substrate. The movement of the metal further redistributes the polymer. In the non-release fixed regions, the polymer reflow seals the metal edges, preventing electrical shorting to adjacent metal edges during subsequent plating processes.

FIG. 4 is a flow chart that describes the operations taken during the fabrication of a coil using one embodiment of the described invention. Blocks 404 to 432 describe the formation of the structure of FIG. 1. In Block 404, a release material is deposited over at least a portion of a substrate 100. The release material may be an etchable materials such as Si, Ti, SiO2 and may be deposited and patterned using a variety of methods including, but not limited to lithography and printing. In block 408, layers of stress-engineered thin film are deposited in a manner that results in an internal stress gradient. Examples of the previously described techniques of deposition include sputtering under gradually increasing pressures to generate a stress gradient, or varying the electrical currents during plating to generate the stress gradient.

After stress-engineered thin film deposition, a polymer is deposited in block 412. The polymer may include two components, a first component deposited over part of the release portion of a coil winding loads the release portion. A second component deposited near winding edges in the ground plane helps to seal and electrically isolate the individual winding edges during future plating operations. Various methods may be used to deposit and pattern the polymer, including printing the polymer, using photolithographic techniques to pattern the polymer and other techniques known to those of skill in the art.

In block 416, an etchant removes the release layer. Release layer removal separates the release portion of the stress-engineered thin film from the underlying substrate. In block 420, the sample including the polymer is pre-annealed. The pre-anneal may be performed at any time after polymer deposition. Thus the pre-anneal may occur before or after release etching. The pre-anneal is typically done at a temperature between 175 and 195 degrees centigrade, and is done more typically between 180 and 190 degrees centigrade or as close to 185 degrees centigrade as possible. Typically, the pre-anneal temperature is maintained for a time period of between 0.5 and 3 minutes. It should be understood that the pre-anneal is optional, however it has been experimentally determined that pre-annealing prior to performing a vapor reflow of the polymer substantially improves pattern definition. It has also been experimentally determined that pre-anneal temperatures at 175 degrees and 195 degrees centigrade are substantially less effective then pre-anneals at 185 degrees centigrade. Accurate pattern definition is particularly helpful in preventing short circuits between adjacent coils during plating. Ideally, the coil should be electrically isolated when used at high frequencies which can be on the order of giga-hertz.

In block 424, the sample is placed inside a chamber and exposed to acetone vapors. Exposure may occur at room temperature (typically between 10 and 45 degrees centigrade) for a period of 1 to 3 minutes in a sealed acetone vapor environment. When extremely tight control is needed, pumps may be used to maintain a vacuum and valves may precisely control vapor flow and acetone partial pressures. However, placing acetone in a sealed chamber with the sample at room temperature for a sufficient time period generates sufficient acetone vapor concentrations to soften the polymer and allow curling of the release portion of the stress-engineered thin film.

After polymer reflow, the coil is plated in block 428. Plating forms a thin layer of high conductivity metal, such as copper, onto the exposed portions of the coil. The plating improves coil conductivity. When the coil serves as an inductor, reducing the coil resistance improves the Q factor. The plated layer is typically less than 20 micrometers thick. However, in an inductor the skin effect confines current to the outer surface of the coil. Due to the skin effect, the outer layer conductivity dominates the high frequency resistance of the inductor loop. Plating also improves the connection where the coil windings close on themselves during assembly.

The plating process also attaches high conductivity metal to exposed portions of the coil in the ground plane. Since there is minimal spacing, often less than 15 micrometers, separating adjacent windings, slight additions of excess conductor plating material can create an electrical short between adjacent windings. Thus plating should be controlled to prevent short circuits. One method of preventing shorts uses reflowed polymer to seal coil edges in the ground plane. Sealing the winding metal edges prevents plating material from laterally growing from the edge of a first coil winding to contact an adjacent coil winding and creating an electrical short.

After plating, remaining polymer may be removed as shown in block 432. Because the polymer has not been heated beyond the temperatures used in the pre-anneal, the polymer typically has not been burned. The lack of heating beyond the pre-anneal avoids polymer burning and facilitates polymer removal. Thus a standard polymer remover such as liquid acetone can be used to chemically remove the polymer.

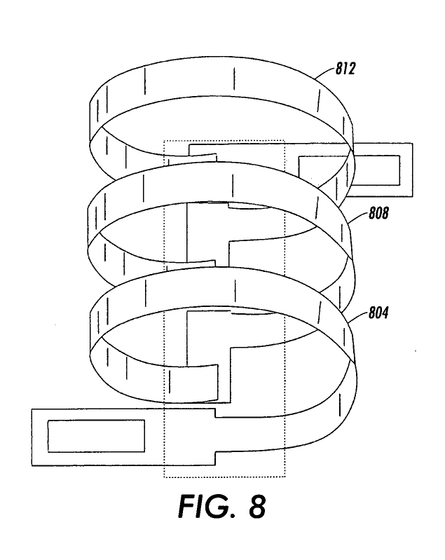

FIG. 8 shows a general view of the coil structure including a plurality of windings 804, 808, 812 that can be formed from the mask of FIG. 2. As previously described, each winding 804, 808, 812 corresponds to the release portions of FIG. 4. As previously described, at the ground plane, each winding should be electrically isolated from adjacent windings.

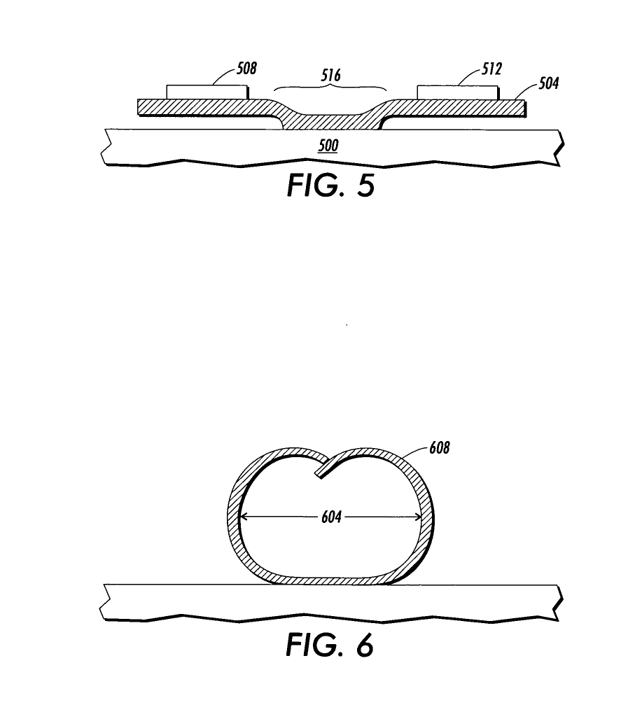

FIGS. 2 and 8 show one example of a mask and a resulting coil structure, however other geometries are also possible. FIG. 5 shows a side view of one example an alternative structure used to from a coil. In FIG. 5, the release portion includes two opposite release segments of a stress-engineered thin film 504. Each release segment includes a corresponding polymer loading layer 508, 512. Polymer may also be used to seal the coil edges at the ground plane 516 where the metal 504 contacts substrate 500.

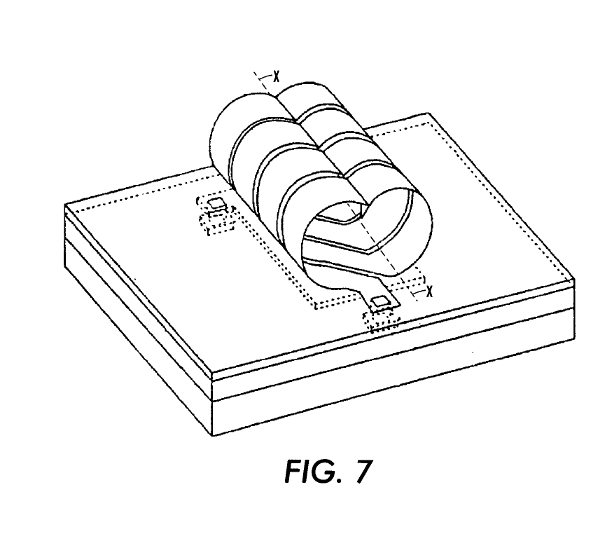

FIG. 6 shows a side cross sectional view and FIG. 7 shows a perspective view of the coil that may be formed using the opposing release segments of FIG. 5. During load layer relaxation, the release layers move upward to come together and form a coil winding, such as winding 608 as shown in FIG. 6. Typical example coil spring diameters 604 range between 590 and 580 micrometers although other diameters are also possible.

Although two example coils have been shown, numerous other coil structures may be formed. Examples of alternative coil structures are described in U.S. Pat. No. 6,621,141 entitled Out-of-Plane Microcoil With Ground Plane Structure by Van Schuylenbergh et al. which is hereby incorporated by reference in its entirety.

The preceding description includes a number of details such as dimensions, temperatures, types of material and example coil implementations. Such details are intended to facilitate understanding of the invention and provide examples. Such details should not be used, and are not intended, to limit the invention. Instead, the invention should only be limited by the claims, as originally presented and as they may be amended, encompass variations, alternatives, modifications, improvements, equivalents, and substantial equivalents of the embodiments and teachings disclosed herein, including those that are presently unforeseen or unappreciated, and that, for example, may arise from applicants/patentees and others.

What is claimed is:

1. A method of softening a polymer layer deposited over a stress engineered thin film comprising:
forming a polymer layer over a portion of a stress-engineered thin film structure;
placing the thin film structure in an enclosed environment; and,
subjecting the polymer to a regulated solvent vapor to soften the polymer and enable the stress engineered thin film to change position.

2. The method of claim 1 wherein the polymer is a load layer deposited over a release portion of the thin film at a first position, the thin film including an internal stress gradient such that when the operation of exposing the polymer to an solvent vapor occurs, a release portion of the thin film moves to a second position, the second position being different from the first position.

3. The method of claim 1 wherein the polymer is deposited near an edge of the metal in the ground plane, the softening being sufficient to reflow the polymer such that the reflow of the polymer seals an edge of the thin film.

4. The method of claim 3 further comprising the operation of:
plating the thin film with a high conductivity metal, the reflow of the polymer to prevent plating of the edge of the metal.

5. The method of claim 1 further comprising the operation of:
annealing the polymer at a temperature between 175 and 195 degrees centigrade prior to exposing the polymer to a solvent vapor.

6. The method of claim 1 wherein the polymer softening occurs at room temperature.

7. The method of claim 1 wherein the solvent vapor concentration is between 0.1% and 70% of the ambient environment.

8. The method of claim 2 further comprising the operations of:
depositing at least the release portion of the thin film by sputtering several sublayers to form the release portion of the thin film, the release portion formed from upper sublayers sputtered under a first pressure and lower sublayers sputtered under a second pressure, the second pressure being different from the first pressure, to create a stress gradient in the thin film release portion.

9. The method of claim 5 wherein the annealing temperature is further confined to between 180 and 190 degrees centigrade.

10. The method of claim 1 wherein air surrounding the polymer is saturated with solvent vapor.

11. The method of claim 1 wherein regulation of solvent vapor further comprises:
placing the polymer and thin film in a reflow chamber; and,
placing a fixed amount of liquid solvent in the sealed chamber such that the liquid solvent does not contact the polymer, allowing the solvent to evaporate and form the solvent vapor that softens the polymer.

12. The method of claim 1 wherein the regulation of solvent vapor further comprises:
placing the polymer and thin film in a reflow chamber;
flowing air in at a predetermined rate; and,
flowing solvent vapor into the reflow chamber at a predetermined rate such that a desired partial pressure of solvent is obtained.

13. A method of softening a polymer load layer comprising:
depositing a release layer over a substrate;
depositing a release portion of a stress engineered thin film over the release layer;
placing a polymer load layer over the release portion of the stress engineered thin film; and,
exposing the polymer to a regulated solvent vapor, the solvent vapor softens the polymer and allows the release portion of the stress engineered layers to change position.

14. The method of claim 13 wherein method further comprises:
depositing the release portion of the metal in layers such that an internal stress gradient is formed in the metal.

15. The method of claim 14 further comprising:
depositing polymer within 5 micrometers of an edge of an electrode, the polymer reflow to seal the edge of the electrode.

16. The method of claim 13 further comprising:
annealing the polymer prior to softening the polymer.

17. The method of claim 16 wherein the annealing occurs at a temperature between 180 degrees centigrade and 190 degrees centigrade.

18. The method of claim 13 wherein the softening allows the release portion of the thin film to curl out of the plane and contact another release portion such that the two release portions form a winding of a coil.

19. The method of claim 13 wherein the polymer softening occurs at room temperature between 10 and 45 degrees centigrade.

20. The method of claim 13 wherein the solvent vapor is generated by boiling the solvent.

21. The method of claim 13 wherein the thin film and polymer is positioned above liquid solvent but does not come into contact with the liquid solvent.

22. The method of claim 13 wherein the concentration of solvent vapor is between 0.1% and 70% of the ambient environment.

23. The method of claim 13 wherein the softening is sufficient to cause polymer reflow, the reflow to seal an edge of the stress engineered thin film.

24. The method of claim 23 further comprising the operation of:
annealing the polymer at a temperature between 180 to 190 degrees centigrade prior to polymer reflow.

25. The method of claim 13 wherein regulation of solvent vapor further comprises:
placing the polymer and thin film in a reflow chamber; and,
placing a fixed amount of liquid solvent in the sealed chamber such that the liquid solvent does not contact the polymer, allowing the solvent to evaporate and form the solvent vapor that softens the polymer.

26. The method of claim 13 wherein the regulation of solvent vapor further comprises:
placing the polymer and thin film in a reflow chamber;
flowing air in at a predetermined rate; and,
flowing solvent vapor into the reflow chamber at a predetermined rate such that a desired partial pressure of solvent is obtained

27. An intermediate structure for forming a coil comprising:
a substrate;
a stress engineered thin film structure, a first portion of the stress engineered thin film structure bonded to the substrate and a second portion of the stress engineered thin film structure released from the substrate;
a polymer load layer deposited over the second portion of the stress engineered thin film structure; and,
a solvent vapor surrounding the polymer load layer, the solvent vapor having a concentration between 0.1% and 70% of the ambient environment, allowing the solvent vapor to soften the polymer load layer.
